(19) United States
(12) Patent Application Publication
(10) Pub. No.: US 2005/0280474 A1
(43) Pub. Date: Dec. 22, 2005

(54) Method of reducing the fractional spurious and a fractional N-PLL oscillator reducing the fractional spurious

(75) Inventor: Satoshi Roppongi, Kanagawa (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/149,645

(22) Filed: Jun. 10, 2005

(30) Foreign Application Priority Data
Jun. 16, 2004 (JP) 2004-177979

(51) Int. Cl. H03L 7/00

(52) U.S. Cl. 331/16

(57) ABSTRACT

A method for reducing the fractional spurious in a fractional N-PLL oscillator comprising a phase comparator having nonlinear elements and a variable frequency oscillator that responds to the low frequency component of output signals of the phase comparator and with which reference signals and signals obtained by dividing the output signals of the variable frequency oscillator are input to the phase comparator, wherein the oscillation frequency component of the variable frequency oscillator is eliminated from the signals input to the phase comparator and the fractional spurious is thereby reduced. The oscillation frequency component of the variable frequency oscillator is eliminated using a gate in the drawings.

### FIELD OF THE INVENTION

The present invention pertains to a fractional N-PLL circuit.

### DISCUSSION OF THE BACKGROUND ART

The phase comparator is an indispensable structural element of the phase-locked loop (PLL). Phase comparators are one of the factors involved in the generation of a spurious signal component or spurious that results in a reduction in the S/N ratio of output signals of the PLL. For years attempts have been made to reduce the spurious attributed to phase comparators (for instance, refer to JP (Kokai) 11[1999]-74,734 (page 3, FIG. 3)).

The fractional N-PLL is a type of PLL. A block diagram showing the general structure of a fractional N-PLL oscillator is shown in FIG. 1. A fractional N-PLL oscillator 100 in the drawing comprises a reference signal source 110, a phase comparator 120, a low pass filter 130, a voltage controlled oscillator 140, and a fractional N divider 150. The voltage controlled oscillator is hereafter referred to as a “VCO.” Moreover, the low pass filter is called an “LPF.” Phase comparator 120 detects and outputs the phase difference between the output signals of the reference signal source 110 and the output signals of the fractional N divider 150. LPF 130 filters the output signals of phase comparator 120 and outputs the product to VCO 140. VCO 140 changes the frequency of the output signals in accordance with the output signals of LPF 130. Fractional N divider 150 divides the output signals of VCO 140 by a predetermined dividing ratio and outputs the product to phase comparator 120.

A spurious component is inherent to a fractional N-PLL with the above-mentioned structure. This inherent spurious is called a fractional spurious in the present Specification. When regarded as a spectrum, a fractional spurious in a spurious component manifested on both sides of the output signals of VCO 140 and the offset frequency relative to the frequency of the output signals of VCO 140 is equal to the difference between the frequency of the output signals of VCO 140 and the higher harmonic frequency of the output signals of reference signal source 110, or the frequency closest to the frequency of the output signals of the VCO 140.

This fractional spurious cannot be reduced using conventional anti-spurious technology. Therefore, the object of the present invention is to reduce the fractional spurious.

### SUMMARY OF THE INVENTION

It became clear that this fractional spurious is caused by the distortion component that is produced when the signals input to a phase comparator and the VCO output signals connected to the phase comparator and to the circuit around the phase comparator through the route that wasn't intended are intermodulated. In order to reduce the fractional spurious, the present invention eliminates the VCO output signal component from the signals input to the phase comparator and thereby reduces or eliminates the distortion generated inside the phase comparator as a result of the intermodulation of VCO output signals and signals input to the phase comparator.

A method for reducing the fractional spurious in a fractional N-PLL oscillator comprising a phase comparator having nonlinear elements and a variable frequency oscillator that responds to the low frequency component of the output signals of the phase comparator and with which reference signals and signals obtained by dividing the output signals of the variable frequency oscillator are input to the phase comparator, this method being characterized in that it comprises a step wherein the oscillation frequency component of the variable frequency oscillator is eliminated from the signals input to the phase comparator.

The present invention also pertains to a fractional N-PLL oscillator comprising a phase comparator having nonlinear elements and a variable frequency oscillator that responds to the low frequency component of the output signals of the phase comparator and with which reference signals and signals obtained by dividing the output signals of the variable frequency oscillator are input to the phase comparator, this oscillator being characterized in that it comprises a means for eliminating the oscillation frequency component of the variable frequency oscillator before inputting signals to the phase comparator such that the fractional spurious is thereby reduced.

Preferably, the elimination means is a low pass filter. Alternatively, the elimination means is a gate for outputting binary signals in response to input signals. The gate has a power source for eliminating or reducing the oscillation frequency component of the variable frequency oscillator.

A signal circuit may optionally be disposed between the phase comparator and the elimination means, wherein the signal circuit has a structure such that the oscillation frequency component from the variable frequency oscillator is prevented from entering the circuit.

Preferably, the phase comparator is a dual flip-flop phase comparator.

The present invention provides a phase comparator with which the fractional spurious in a fractional N-PLL can be reduced when compared to the prior art. By means of the present invention, the additional circuits for reducing the fractional spurious require less space.

### BRIEF DESCRIPTION OF THE DRAWINGS

FIG. 1 is a block diagram showing a fractional N-PLL oscillator 100 of the prior art.

FIG. 2 is a block diagram showing the first embodiment of the present invention, a fractional N-PLL oscillator 200.

FIG. 3 is a drawing showing the inside structure of a phase comparator 230.

FIG. 4 is a block diagram showing the second embodiment of the present invention, a fractional N-PLL oscillator 300.

FIG. 5 is a drawing showing the output spectrum of a fractional N-PLL oscillator of the prior art.

FIG. 6 is a drawing showing the output spectrum of the fractional N-PLL oscillator of the present invention.

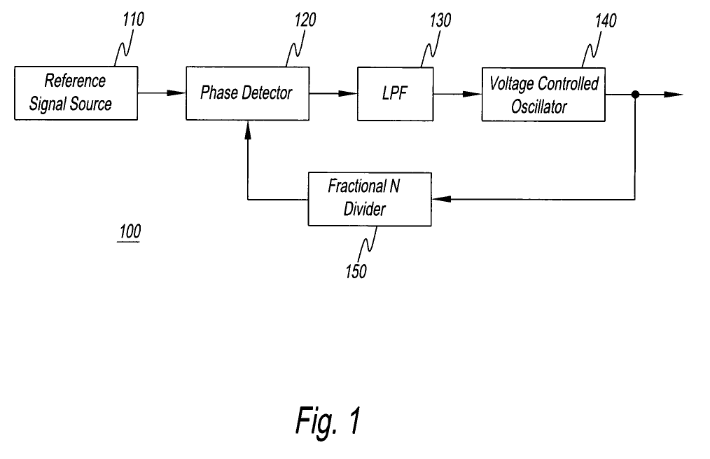

### DETAILED DESCRIPTION OF THE PREFERRED EMBODIMENT

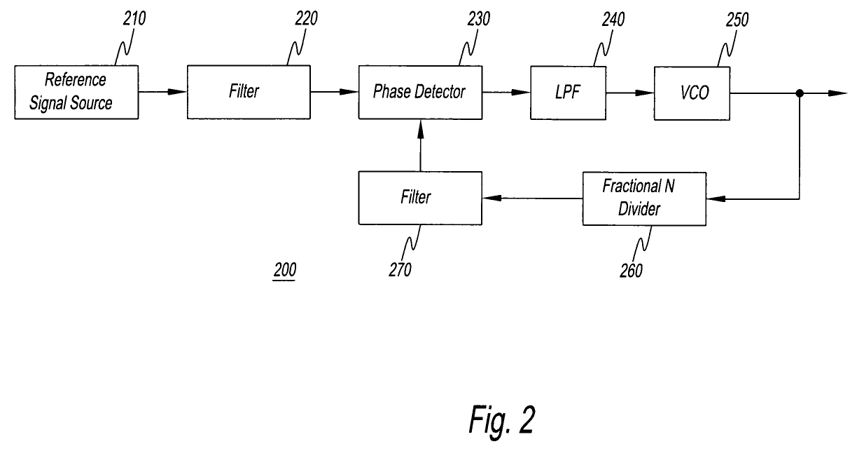

Preferred embodiments of the present invention will now be described while referring to the attached drawings as necessary. The first embodiment of the present invention is a fractional N-PLL oscillator 200. FIG. 2 is a block diagram showing the general structure of fractional N-PLL oscillator 200. Fractional N-PLL oscillator 200 in the drawing comprises a reference signal source 210, a filter 220, a phase comparator 230, an LPF 240, a VCO 250, a fractional N divider 260, and a filter 270. The output signals of reference signal source 210 are input via filter 220 to phase comparator 230. The output signals of fractional N divider 260 are input via filter 270 to phase comparator 230. Phase comparator 230 detects the phase difference between these two input signals. The output signals of phase comparator 230 are input via LPF 240 to VCO 250. VCO 250 is an oscillator that varies its oscillation frequency in accordance with input signals. In short, VCO 250 varies the oscillation frequency in response to the output signals of phase comparator 230. Fractional N divider 260 divides the output signals of VCO 250 by a predetermined dividing ratio M.

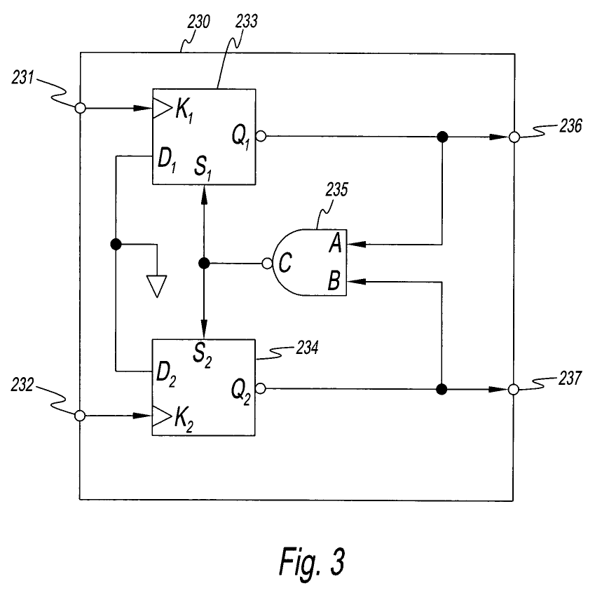

Phase comparator 230 will now be described in further detail. FIG. 3 is a block diagram showing the general structure of phase comparator 230. Phase comparator 230 in the drawing comprises a first input terminal 231, a second input terminal 232, a D flip-flop 233, a D flip-flop 234, an NAND gate 235, a first output terminal 236, and a second output terminal 237.

The signals received at first input terminal 231 are applied to a clock input terminal K₁ of D flip-flop 233. The signals received at second input terminal 232 are applied to a clock input terminal K₂ of D flip-flop 234. A low logic level (Low) is applied to a data input terminal D₁ of D flip-flop 233 and to a data input terminal D₂ of D flip-flop 234. An inverted data terminal Q₁ of D flip-flop 233 and an inverted data output terminal Q₂ of D flip-flop 234 are connected to input terminal A and input terminal B of NAND gate 235, respectively. Moreover, inverted data output terminal Q₁ of D flip-flop 233 is connected to output terminal 236. Inverted data output terminal Q₂ of D flip-flop 234 is connected to output terminal 237. An output terminal C of NAND gate 235 is connected to a set terminal S₁ of D flip-flop 233 and a set terminal S₂ of D flip-flop 234. Phase comparator 230 is a so-called dual flip-flop phase detecting unit, and D flip-flops 233 and 234 can be replaced by a JK flip-flop, or other flip-flop. Moreover, a reset terminal can be used in place of set terminals S₁ and S₂. In this case, replacing the inverted data output terminals with non-inverted data outputs and other modifications are necessary, and these modifications most likely can be easily implemented by persons skilled in the art.

D flip-flops 233 and 234 and NAND gate 235 are made from transistors and other nonlinear components. Ideally, transistors operate in saturated regions and can be approximated with linear components, but nonlinearity will actually remain. Consequently, when an undesirable frequency component is present in the logic circuit, it will produce an intermodulation distortion, even if this component is extremely small. Moreover, even if this component is so small that it will not have any influence on operation as a logic circuit, the influence of the distortion component on the output signals of the phase comparator will be noticeable.

Therefore, filter 220 and filter 270 have cut-off properties such that the oscillation frequency component (output signal component) of VCO 250 can be eliminated from the output signals of reference signal source 210 and the output signals of fractional N divider 260 in order to prevent the output signals of the VCO 250 from entering phase comparator 230. The oscillation frequency of VCO 250 is higher than the frequency of the input component of phase comparator 230. Consequently, filter 220 and filter 270 are LPFs or band pass filters.

Moreover, the oscillation frequency component (output signal component) of VCO 250 must not be allowed to enter the signal circuit between filter 220 and phase comparator 230 or the signal circuit between filter 270 and phase comparator 230. Therefore, filter 220 and phase comparator 230 are brought close to one another and filter 270 and phase comparator 230 are brought close to one another and these signal circuits are thereby shortened as much as possible. If these signal circuits cannot be made short enough, they are made from shielded cables and similar elements.

The power source of VCO 250 and the power source of phase comparator 230 are isolated and filters are added near the power source terminals of phase comparator 230 in order to keep the oscillation frequency component (output signal component) of VCO 250 from entering phase comparator 230 via the power source circuits. Filters added near the power source terminals have cut-off properties such that the oscillation frequency component (output signal component) of VCO 250 can be eliminated from the power source. They can also have cut-off properties such that the oscillation frequency component of VCO 250 is reduced to such an extent that it can be disregarded.

However, there are cases in which the oscillation frequency of VCO 250 and the frequency of the output signals of reference signal source 210 are similar and cases in which the anticipated properties are not obtained with filter 220 and filter 270. In other words, there are cases wherein the oscillation frequency component (output signal component) of VCO 250 cannot be thoroughly eliminated from the output signals of reference signal source 210 and the output signals of fractional N divider 260 and the fractional spurious cannot be eliminated as expected. A second embodiment of the present invention that solves such problems is described below.

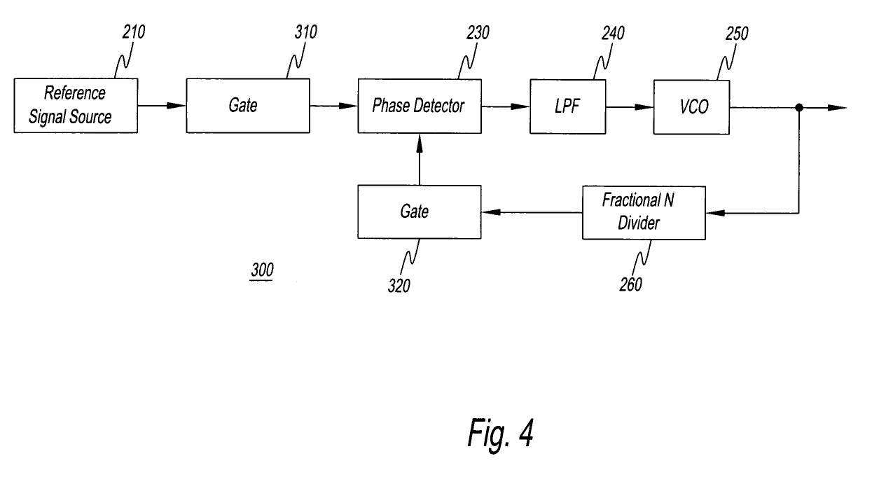

The second embodiment of the present invention is a fractional N-PLL oscillator 300. FIG. 4 is a block diagram showing the general structure of fractional N-PLL oscillator 300. The elements in FIG. 4 that are the same as in FIG. 2 are represented by the same symbols and are not described again. Fractional N-PLL oscillator 300 in the drawing comprises a reference signal source 210, a gate 310, a phase comparator 230, an LPF 240, a VCO 250, a fractional N divider 260, and a gate 320. The output signals of reference signal source 210 are input via gate 310 to phase comparator 230. The output signals of fractional N divider 260 are input via gate 320 to phase comparator 230. Phase comparator 230 detects the phase difference between these two input signals. The output signals of phase comparator 230 are input via LPF 240 to VCO 250. VCO 250 is an oscillator that varies its oscillation frequency in accordance with the input signals. In short, VCO 250 varies its oscillation frequency in response to the output signals of phase comparator 230. Fractional N divider 260 divides the output signals of VCO 250 by a pre-determined dividing ratio M.

Gate 310 and gate 320 are logic elements or logic circuits that output binary signals in response to input signals. Consequently, these output signals ideally are represented by a high or low logic level. Moreover, even if some or all of these output signals oscillate, these output signals should not contain the oscillation frequency component (output signal component) of VCO 250. Moreover, if these output signals do contain the oscillation frequency component (output signal component) of VCO 250, this oscillation component should be kept small enough that the fractional spurious contained in the output signals of VCO 250 can be disregarded. In other words, gate 310 and gate 320 have properties such that the oscillation frequency component (output signal component) of VCO 250 can be eliminated from the output signals of reference signal source 210 and the output signals of fractional N divider 260 so that the output signals of the VCO 250 will not enter phase comparator 230.

Moreover, the oscillation frequency component (output signal component) of VCO 250 must not be allowed to enter the signal path between gate 310 and phase comparator 230 as well as the signal path between gate 320 and comparator 230. Therefore, gate 310 and phase comparator 230 are brought close to one another and gate 320 and phase comparator 230 are brought close to one another and these signal circuits are thereby shortened as much as possible. If these signal circuits cannot be made short enough, they are made from shielded cables and similar elements.

The following modifications can be applied to the above-mentioned embodiments.

First, phase comparator 230 in the first embodiment can comprise filter 220 and filter 270, and there can be one phase comparator. In this case, the cut off properties of the filter housed inside the phase comparator can be designed such that external adjustment is possible. Moreover, phase comparator 230 in the second embodiment can comprise gate 310 and gate 320, and there can be one phase comparator.

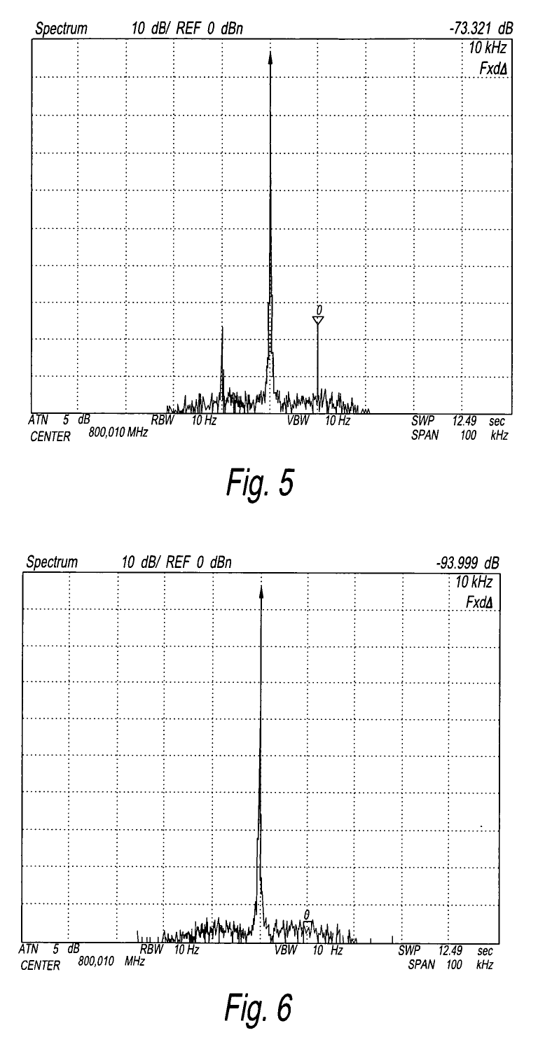

Refer to FIG. 5 and FIG. 6 in order to clarify the effect of the present invention. FIG. 5 is a drawing showing the output spectrum of a conventional fractional N-PLL oscillator. FIG. 6 is a drawing showing the output spectrum of the fractional N-PLL oscillator of the present invention. The y-axis in both drawings indicates power. Moreover, the x-axis indicates frequency. The entire width of the x-axis is 100 kHz and the axis is divided into 10 segments by broken lines. The output signal frequency of the reference oscillator is 5 MHz. The dividing ratio of the fractional N divider is 160.002. The oscillation frequency of the VCO is 800.01 MHz. There is one spurious component for every 10 kHz of offset on both sides of the carrier in FIG. 5. These fractional spurious components are produced when the 160th higher harmonic component (800 MHz) of the output signals of the reference oscillator and the output signal component (800.01 MHz) of the VCO are intermodulated inside the phase comparator. In other words, a fractional spurious is generated when the number of divisions of the fractional N divider is not an integer. On the other hand, the presence of this spurious component cannot be recognized in FIG. 6. This effect is virtually the same in both the first and second embodiments.

1. A method for reducing the fractional spurious in a fractional N-PLL oscillator comprising a phase comparator having nonlinear elements and which outputs phase comparator output signals, and a variable frequency oscillator that responds to a low frequency component of said phase comparator output signals and outputs variable frequency oscillator output signals, said method comprising:
inputting a reference signal and divided signals to said phase comparator, wherein said divided signals are obtained by dividing said variable frequency oscillator output signals by a predetermined ratio; and
eliminating an oscillation frequency component from said divided signals input to said phase comparator.

2. A fractional N-PLL oscillator comprising:
a phase comparator having nonlinear elements and which outputs phase comparator output signals;
a variable frequency oscillator that responds to a low frequency component of said phase comparator output signals and outputs variable frequency oscillator output signals; and
a means for eliminating an oscillation frequency component from said variable frequency oscillator output signals before inputting said variable frequency oscillator output signals to said phase comparator such that the fractional spurious is thereby reduced.

3. The fractional N-PLL oscillator according to claim 2, wherein said elimination means is a low pass filter.

4. The fractional N-PLL oscillator according to claim 2, wherein said elimination means is a gate.

5. The fractional N-PLL oscillator according to claim 4, wherein said gate has a power source for eliminating or reducing said oscillation frequency component of said variable frequency oscillator output signals.

6. The fractional N-PLL oscillator according to claim 2, further comprises a signal circuit disposed between said phase comparator and said elimination means, wherein said signal circuit comprises a structure such that said oscillation frequency component is prevented from entering said variable frequency oscillator.

7. The fractional N-PLL oscillator according to claim 2, wherein said phase comparator is a dual flip-flop phase comparator.
